(19) United States
(12) Patent Application Publication
(10) Pub. No.: US 2025/0251555 A1
(43) Pub. Date: Aug. 7, 2025

(54) OPTICAL DEVICES AND METHODS OF MANUFACTURE

(71) Applicant: Taiwan Semiconductor Manufacturing Co., Ltd., Hsinchu (TW)

(72) Inventors: Tai-Chun Huang, New Taipei City (TW); Stefan Rusu, Sunnyvale, CA (US)

(21) Appl. No.: 18/646,326

(22) Filed: Apr. 25, 2024

Related U.S. Application Data
(60) Provisional application No. 63/550,638, filed on Feb. 7, 2024.

(51) Int. Cl. G02B 6/42; G06N 3/067

(52) U.S. Cl. CPC G02B 6/4283; G02B 6/4266; G06N 3/0675

(57) ABSTRACT

Optical devices and methods of manufacture are presented in which a photonic neural net with convolution units is formed within a photonic integrated circuit. The photonic integrated circuit is bonded to a first semiconductor device such as a memory device and is electrically connected to a second semiconductor device such as a system-on-chip device.

### PRIORITY CLAIM AND CROSS-REFERENCE

This application claims the benefit of U.S. Provisional Application No. 63/550,638, filed on Feb. 7, 2024, which application is hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 illustrate formation of a first optical package, in accordance with some embodiments.

FIGS. 6A-6B illustrate a photonic neural network, in accordance with some embodiments.

FIGS. 7A-7D illustrate a convolution module, in accordance with some embodiments.

FIG. 8A-8C illustrate the convolution module incorporated into various optical components, in accordance with some embodiments.

FIGS. 9A-9E illustrate a convolution module utilizing metal heaters, in accordance with some embodiments.

FIGS. 10A-10C illustrate a convolution module utilizing silicon heaters, in accordance with some embodiments.

FIGS. 11-14 illustrate formation of a first photonic package, in accordance with some embodiments.

FIGS. 15A-15C illustrate bonding the first photonic package and a second semiconductor device on an interposer substrate, in accordance with some embodiments.

FIGS. 16A-16B illustrate bonding a memory device of the first photonic package to the interposer substrate, in accordance with some embodiments.

FIGS. 17A-17B illustrate bonding the photonic integrated circuit and the second semiconductor device to the memory device, in accordance with some embodiments.

FIGS. 18A-18B illustrate bonding the memory device and the second semiconductor device to the photonic integrated circuit, in accordance with some embodiments.

FIGS. 19A-19B illustrate bonding the memory device to the system-on-chip device, in accordance with some embodiments.

FIGS. 20A-20B illustrate bonding the system-on-chip device to the memory device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which silicon photonic technology is utilized in a Computation-in-Memory (CIM) architecture. The embodiments presented, however, are intended to be illustrative and are not intended to limit the ideas presented to the precise embodiments described. Rather, the ideas presented may be incorporated into a wide variety of embodiments, and all such embodiments may be included within the overall scope of the disclosure.

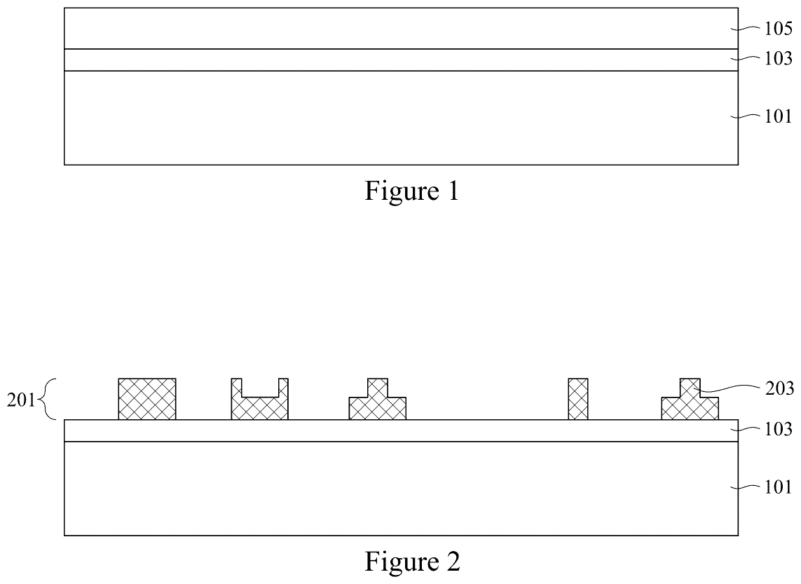

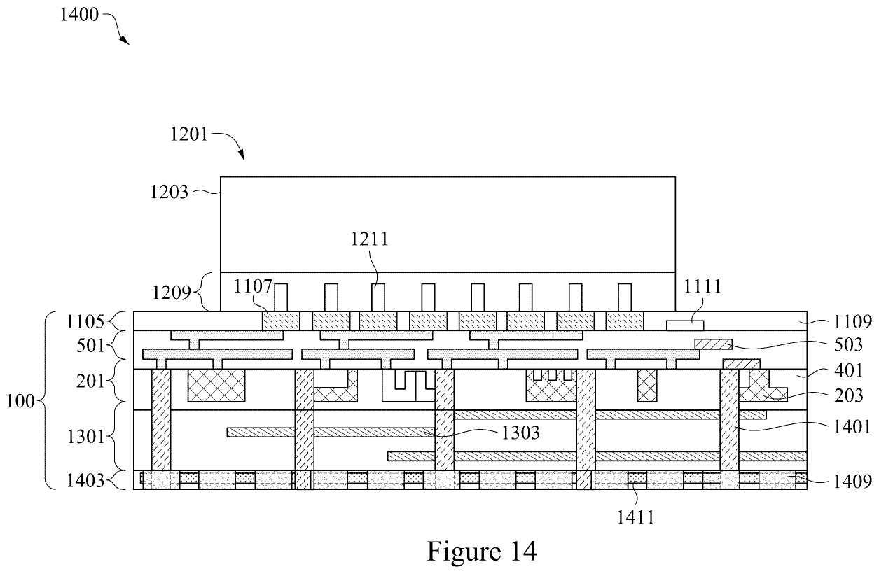

With reference now to FIG. 1, there is illustrated an initial structure of an photonic integrated circuit (PIC) 100 (seen in one completed form in FIG. 14), in accordance with some embodiments. In the particular embodiment illustrated in FIG. 1, the photonic integrated circuit 100 comprises at this stage a first substrate 101, a first insulator layer 103, and a layer of material 105 for a first active layer 201 of first optical components 203 (not separately illustrated in FIG. 1 but illustrated and discussed further below with respect to FIG. 2). In an embodiment, at a beginning of the manufacturing process of the photonic integrated circuit 100, the first substrate 101, the first insulator layer 103, and the layer of material 105 for the first active layer 201 of first optical components 203 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 201 and can additionally, in some embodiments, serve as a portion of cladding material that surrounds the subsequently manufactured first optical components 203 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. However, any suitable material and method of manufacture may be used.

The material 105 for the first active layer 201 is initially (prior to patterning) a conformal layer of material that will be used to begin manufacturing the first active layer 201 of the first optical components 203. In an embodiment the material 105 for the first active layer 201 may be a translucent material that can be used as a core material for the desired first optical components 203, such as a semiconductor material such as silicon, germanium, silicon germanium, combinations of these, or the like, while in other embodiments the material 105 for the first active layer 201 may be a dielectric material such as silicon nitride or the like, although in other embodiments the material 105 for the first active layer 201 may be III-V materials, lithium niobate materials, or polymers. In embodiments in which the material 105 of the first active layer 201 is deposited, the material 105 for the first active layer 201 may be deposited using a method such as epitaxial growth, chemical vapor deposition, atomic layer deposition, physical vapor deposition, combinations of these, or the like. In other embodiments in which the first insulator layer 103 is formed using an implantation method, the material 105 of the first active layer 201 may initially be part of the first substrate 101 prior to the implantation process to form the first insulation layer 103. However, any suitable materials and methods of manufacture may be utilized to form the material 105 of the first active layer 201.

FIG. 2 illustrates that, once the material 105 for the first active layer 201 is ready, the first optical components 203 for the first active layer 201 are manufactured using the material 105 for the first active layer 201. In embodiments the first optical components 203 of the first active layer 201 may include such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable first optical components 203 may be used.

To begin forming the first active layer 201 of first optical components 203 from the initial material, the material 105 for the first active layer 201 may be patterned into the desired shapes for the first active layer 201 of first optical components 203. In an embodiment the material 105 for the first active layer 201 may be patterned using, e.g., one or more photolithographic masking and etching processes. However, any suitable method of patterning the material 105 for the first active layer 201 may be utilized. For some of the first optical components 203, such as waveguides or edge couplers, the patterning process may be all or at least most of the manufacturing that is used to form these first optical components 203 components.

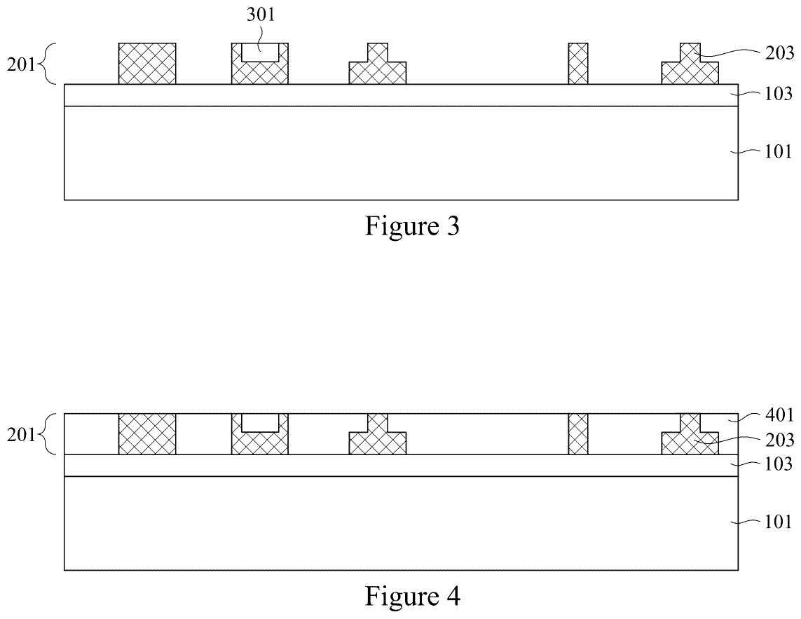

FIG. 3 illustrates that, for those components that utilize further manufacturing processes, such as Mach-Zehnder silicon-photonic switches that utilize resistive heating elements, additional processing may be performed either before or after the patterning of the material for the first active layer 201. For example, implantation processes, additional deposition and patterning processes for different materials (e.g., resistive heating elements, III-V materials for converters), combinations of all of these processes, or the like, can be utilized to help further the manufacturing of the various desired first optical components 203. In a particular embodiment, and as specifically illustrated in FIG. 3, in some embodiments an epitaxial deposition of a semiconductor material 301 such as germanium (used, e.g., for electricity/optics signal modulation and transversion) may be performed on a patterned portion of the material 105 of the first active layer 201. In such an embodiment the semiconductor material 301 may be epitaxially grown in order to help manufacture, e.g., a photodiode for an optical-to-electrical converter. All such manufacturing processes and all suitable first optical components 203 may be manufactured, and all such combinations are fully intended to be included within the scope of the embodiments.

FIG. 4 illustrates that, once the individual first optical components 203 of the first active layer 201 have been formed, a second insulator layer 401 may be deposited to cover the first optical components 203 and provide additional cladding material. In an embodiment the second insulator layer 401 may be a dielectric layer that separates the individual components of the first active layer 201 from each other and from the overlying structures and can additionally serve as another portion of cladding material that surrounds the first optical components 203. In an embodiment the second insulator layer 401 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulator layer 401 has been deposited, the material may be planarized using, e.g., a chemical mechanical polishing process in order to either planarize a top surface of the second insulator layer 401 (in embodiments in which the second insulator layer 401 is intended to fully cover the first optical components 203) or else planarize the second insulator layer 401 with top surfaces of the first optical components 203. However, any suitable material and method of manufacture may be used.

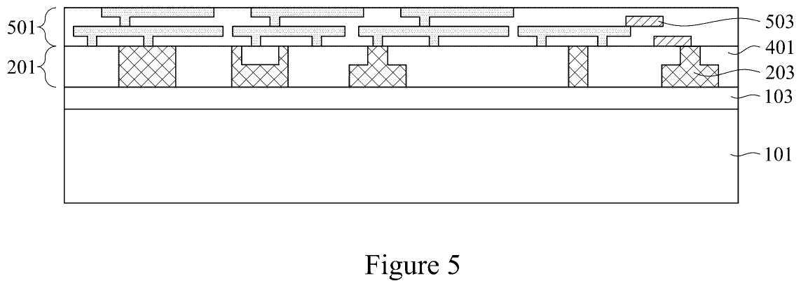

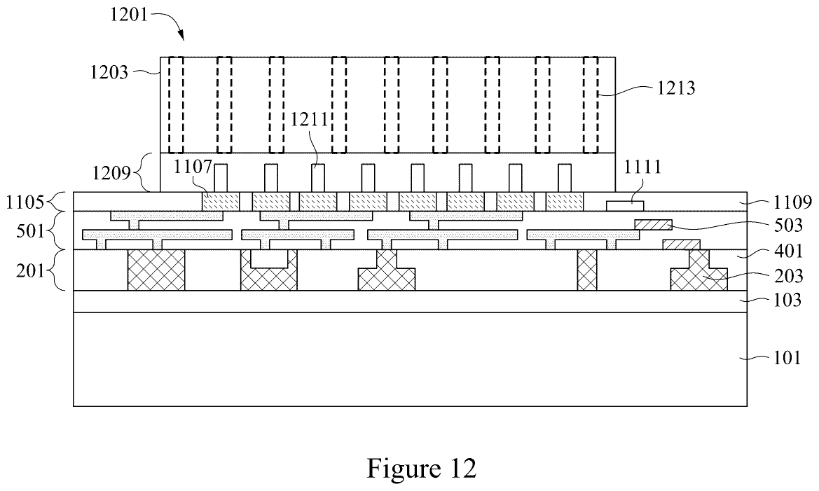

FIG. 5 illustrates that, once the first optical components 203 of the first active layer 201 have been manufactured and the second insulator layer 401 has been formed, first metallization layers 501 are formed in order to electrically connect the first active layer 201 of first optical components 203 to control circuitry, to each other, and to subsequently attached devices (not illustrated in FIG. 5 but illustrated and described further below with respect to FIG. 12). In an embodiment the first metallization layers 501 are formed of alternating layers of dielectric and conductive material and may be formed through any suitable processes (such as deposition, damascene, dual damascene, etc.). In particular embodiments there may be multiple layers of metallization used to interconnect the various first optical components 203, but the precise number of first metallization layers 501 is dependent upon the design of the photonic integrated circuit 100.

Additionally, during the manufacture of the first metallization layers 501, one or more second optical components 503 may be formed as part of the first metallization layers 501. In some embodiments the second optical components 503 of the first metallization layers 501 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components 503.

In an embodiment the one or more second optical components 503 may be formed by initially depositing a material for the one or more second optical components 503. In an embodiment the material for the one or more second optical components 503 may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components 503 has been deposited or otherwise formed, the material may be patterned into the desired shapes for the one or more second optical components 503. In an embodiment the material of the one or more second optical components 503 may be patterned using, e.g., one or more photolithographic masking and etching processes. However, any suitable method of patterning the material for the one or more second optical components 503 may be utilized.

For some of the one or more second optical components 503, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more second optical components 503. For example, implantation processes, additional deposition and patterning processes for different materials, combinations of all of these processes, or the like, and can be utilized to help further the manufacturing of the various desired one or more second optical components 503. All such manufacturing processes and all suitable one or more second optical components 503 may be manufactured, and all such combinations are fully intended to be included within the scope of the embodiments.

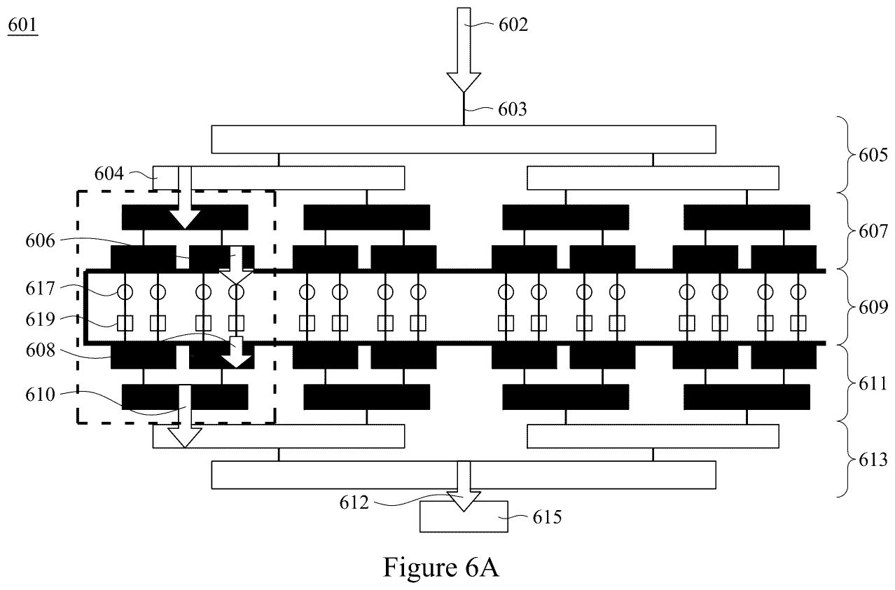

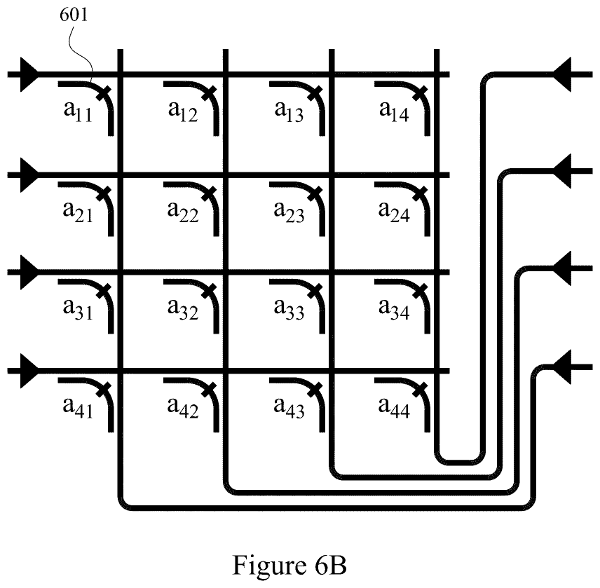

FIG. 6A illustrates a conceptual overview of a portion of a photonic neural network (PNN) that can be implemented within the photonic integrated circuit 100 using the various components and manufacturing processes as described above with respect to the first active layer 201 of the first optical components 203 and the first metallization layers 501. In the particular embodiment illustrated in FIG. 6A, the photonic neural network comprises a plurality of optical cores 601 (only one of which is illustrated in FIG. 6A), wherein each optical core 601 comprises an optical input 603, an optical splitter 605, a first wavelength divisional multiplexor 607, a plurality of convolution modules 609, a second wavelength divisional multiplexor 611, an optical combiner 613, and a photodiode/transimpedance amplifier 615. However, any other suitable modules and configurations may be utilized.

Looking first at the optical input 603, the optical input 603 is utilized in order to receive optical signals 602 or lasers (e.g., from other regions of the photonic integrated circuit 100 or from off the photonic integrated circuit 100) and input the optical signals 602 into the optical splitter 605. In an embodiment the optical input 603 may be a one or more waveguides, couplers, amplifiers, etc., or any other suitable transmission mediums. However, any suitable structures may be used.

The optical input 603 directs the optical signals 602 into the optical splitter 605. In an embodiment the optical splitter 605 comprises one or more waveguides positioned adjacent to each other so that the optical signals 602 may evanescently couple between the individual waveguides, thereby splitting the optical signals 602 between the individual waveguides and forming split optical signals 604. However, any suitable combination of modules may be used.

Once the split optical signals 604 have been formed, the split optical signals 604 may be directed towards the first wavelength division multiplexor 607 within a kernel 614 comprising the first wavelength division multiplexor 607, the convolution modules 609, and the second wavelength divisional multiplexor 611. In an embodiment the first wavelength divisional multiplexor 607 is utilized in order to receive the split optical signals 604 and separate out the split optical signals 604 into different and distinct wavelengths of light to form wavelength optical signals 606. Each wavelength of light may then be sent to an individual one of the plurality of convolution modules 609. In a particular embodiment the first wavelength divisional multiplexer 607 may be similar to the devices described in U.S. patent application Ser. No. 18/166,016, filed on Feb. 8, 2023, and entitled “Optical Device and Method of Fabricating Thereof,” which application is hereby incorporated herein by reference

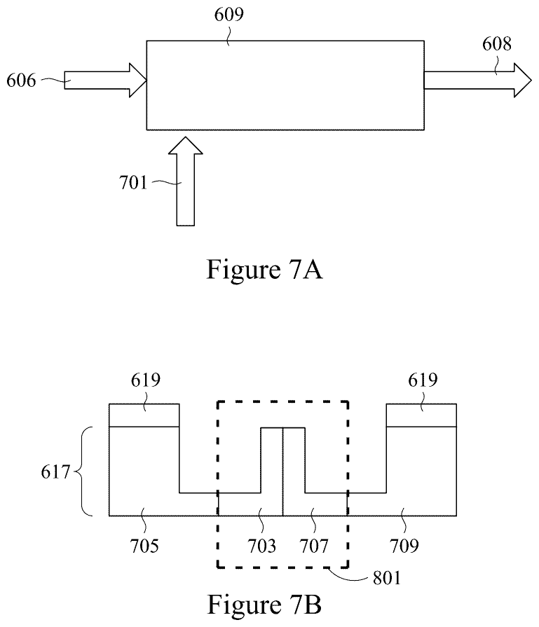

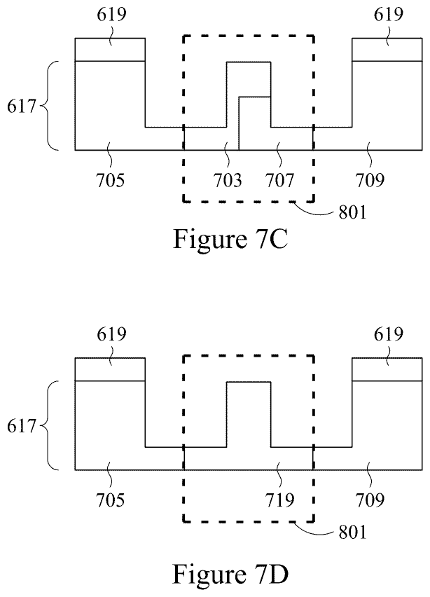

The plurality of convolution modules 609 receive the wavelength optical signals 606 from the first wavelength divisional multiplexor 607 and modulate the wavelength optical signals 606 based on a weighting that is applied to the convolution modules 609. In an embodiment plurality of convolution modules 609 each comprise a modulator unit 617 and a weighting unit 619, each of which is described further below starting with FIG. 7A. The plurality of convolution modules 609 modulate the wavelength optical signals 606 to form modulated optical signals 608.

Once the modulated optical signals 608 have been formed by the plurality of convolution modules 609, the modulated optical signals 608 are sent to the second wavelength divisional multiplexor 611. The second wavelength divisional multiplexor 611 is utilized to either multiplex or de-multiplex the different modulated optical signals 608 into a second modulated optical signal 610. The second modulated optical signal 610 is then routed to the optical combiner 613.

In an embodiment the optical combiner 613 receives the second modulated optical signal 610 from the second wavelength divisional multiplexor 611 and recombines the plurality of optical signals into a single output signal 612. In an embodiment the optical combiner 613 comprises one or more waveguides or other structures positioned adjacent to each other so that the optical signals may evanescently couple between the individual waveguides, thereby combining the recombined optical signals into a single output. However, any suitable devices or combination of devices may be used.

The optical combiner 613 routes the single output signal 612 to the photodiode/transimpedance amplifier 615. In the photodiode/transimpedance amplifier 615 the single output signal 612 is converted into an electrical signal using the photodiode and then amplified for further transmission. However, any suitable modules or combination of modules may be utilized.

By utilizing the optical cores 601, a high-speed modulator receives an electrical signal and performs high-speed optical signal modulation. The signal is then weighted by an optical weighter, which applies the corresponding weights to the signal. The modulator and weighter perform multiplication operations in the optical integrated circuit, and the addition operation is completed by a demultiplexor, allowing the process to achieve convolutional computation.

FIG. 6B illustrates that, in another very particular embodiment, the optical cores 601 may be incorporated into, for example, a different arrangement. For example, in this embodiment the optical core can be incorporated into an array of devices such as an on-chip multiply-accumulate (MAC) unit. However, the incorporation of the optical cores 601 into such an array is intended to be illustrative, as the optical cores 601 may be incorporated into a wide variety of devices. All such devices which may incorporate the optical cores 601 are fully intended to be included within the scope of the embodiments.

FIGS. 7A-7D illustrate a conceptual concept for one of the convolution modules 609 that is used to modulate the wavelength optical signals 606 from the first wavelength divisional multiplexor 607. As illustrated the wavelength optical signals 606 are input into the convolution module 609 along with a modulation signal 701. The convolution module 609 receives the wavelength optical signals 606 and the modulation signal 701 and modulates the wavelength optical signals 606 based on the modulation signal 701 to form the modulated optical signals 608.

FIG. 7B illustrates a cross sectional view of one embodiment of the modulator unit 617 and the weighting unit 619 within the convolution modules 609. In an embodiment the modulator unit 617 may comprise a waveguide 801 such as a silicon waveguide (in embodiments in which the modulator unit 617 is formed as one of the first optical components 203 within the first active layer 201) or else may be a silicon nitride waveguide (in embodiments in which the modulator unit 617 is formed as one of the second optical components 503 within the first metallization layer 501). The material of the waveguide may be patterned to form a lateral PN junction (LPN) modulator for use in a reverse bias or forward bias operation, although any suitable shape may be utilized.

During the manufacturing of the modulator unit 617, the modulator unit may be implanted with dopants to form a first N-doped region 703, a second N-doped region 705, a first P-doped region 707, and a second P-doped region 709. Looking first at the first N-doped region 703, the first N-doped region may be doped with dopants such as phosphorous, arsenic, or the like, using an introduction process such as an implantation process or a diffusion process in order to introduce the dopants into the first N-doped region 703. Once the dopants have been introduced, an anneal may be performed to activate the dopants.

Looking next at the first P-doped region 707, the first P-doped region 707 is formed adjacent to the first N-doped region 703 in order to form a PN junction at the middle of the waveguide 801. In an embodiment the first P-doped region 707 may be doped with dopants such as boron, gallium, or the like, using an introduction process such as an implantation process or a diffusion process in order to introduce the dopants into the first P-doped region 707. Once the dopants have been introduced, an anneal may be performed to activate the dopants.

The second N-doped region 705 and the second P-doped region 709 are formed on opposite sides of the waveguide 801 and are heavily doped regions in order to be metal-like and help assist with an electrical connection to the weighting unit 619. In an embodiment the second N-doped region 705 and the second P-doped region 709 are doped with similar dopants as the first N-doped region 703 and the first P-doped region 707, respectively. However, any suitable dopants may be utilized.

The weighting unit 619 is formed over the modulator unit 617 and is utilized to receive and apply the modulation signal 701 to the wavelength optical signals 606 as the wavelength optical signals 606 traverse through the waveguide 801 comprised of the first N-doped region 703 and the first P-doped region 707. In an embodiment the modulator unit 617 comprises a metal material such as copper, aluminum, etc. that can transmit and apply a bias to the second N-doped region 705 and the second P-doped region 709. In an embodiment the modulator unit 617 may be formed using similar processes and materials as the electrical components of the first metallization layer 501 (e.g., a damascene or dual damascene process). However, any suitable materials and any suitable processes may be utilized.

In operation the modulation signal 701 is routed by the first metallization layer 501 to the weighting unit 619. The weighting unit 619 then applies the modulation signal 701 (e.g., a bias) to the second N-doped region 705 and the second P-doped region 709 (e.g., the N+ region and the P+ region) in order to form a reverse bias at the PN junction between the first N-doped region 703 and the first P-doped region 707. As the reverse bias increases, a depletion region also increases, which causes a carrier concentration to decrease. The decrease in carrier concentration causes the refractive index of the waveguide 801 to increase, thereby modulating the distance that the wavelength optical signals 606 travels through the waveguide 801. By modifying the distance, the overall phase of the wavelength optical signals 606 can be modulated by the modulation unit 617.

FIG. 7C illustrates another embodiment of a vertical PN junction (VPN) phase modulator that may be used as the convolution modules 609 for operation under a reverse bias operating condition. In this embodiment the convolution modules 609 include the first N-doped region 703, the second N-doped region 705, the first P-doped region 707, the second P-doped region 709, and the modulation unit 617, formed using similar processes and materials as the LPN phase modulator described in FIG. 7B. In this embodiment, however, the first N-doped region 703 and the first P-doped region 707 are shaped such that a portion of the first N-doped region 703 extends over the first P-doped region 707. By utilizing these shapes, the contact area between the first N-doped region 703 and the first P-doped region 707 is enlarged as compared to the LPN phase modulator described with respect to FIG. 7B. With such an ability to adjust the contact area between the first N-doped region 703 and the first P-doped region 707, a larger flexibility for tuning the refractive index may be obtained.

FIG. 7D illustrates another embodiment of a Low Speed PIN (LSPIN) phase modulator that may be used as the convolution modules 609 for operation under a forward bias operating condition. In this embodiment the convolution modules 609 include the second N-doped region 705, the second P-doped region 709, and the modulation unit 617 with an intrinsic region 719 located between the second N-doped region 705 and the second P-doped region 709. In an embodiment the second N-doped region 705, the second P-doped region 709, and the modulation unit 617 may be formed using similar processes and materials as the LPN phase modulator described in FIG. 7B. In this embodiment, however, the first N-doped region 703 and the first P-doped region 707 are not formed, and the material remains undoped to form the intrinsic region 719. For example, during the formation process of the second N-doped region 705 and the second P-doped region 709 (e.g., implantation processes), the portions of the waveguide 801 may be protected so that no implantation may occur in this region. In operation, as a reverse bias is increased at the modulation unit 617 and, consequently, at the second N-doped region 705 and the second P-doped region 709, the carrier concentration decreases within the intrinsic region 719, thereby increasing the refractive index of the intrinsic region 719 and of the waveguide 801.

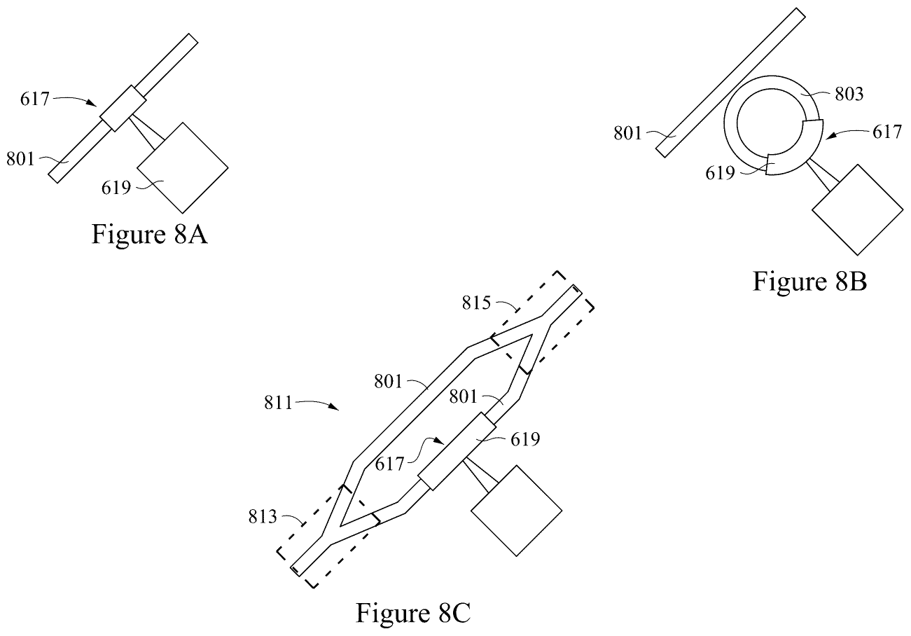

FIGS. 8A-8C illustrate different embodiments of structures into which the convolution modules 609 described above with respect to FIGS. 7A-7D may be incorporated. For example, in looking at FIG. 8A first, the weighting unit 619 and the modulator unit 617 (located within this figure as being beneath the weighting unit 619) are formed to be integrated within a straight waveguide 801 as an in-line modulator. As such, the wavelength optical signals 606 may be modulated as the wavelength optical signals 606 travels through the waveguide 801.

FIG. 8B illustrates another embodiment in which the convolution modules 609 is incorporated into a ring modulator 803. In this embodiment the convolution modules 609 are not placed directly onto the waveguide 801 but are, instead, placed onto a ring modulator 803 that is evanescently coupled to the waveguide 801. As such, the modulation of the convolution modules 609 may be incorporated into the modulation already provided by the ring modulator 803.

FIG. 8C illustrates yet another embodiment in which the convolution modules 609 may be incorporated into a Mach-Zehnder modulator 811. In an embodiment the Mach-Zehnder modulator comprises two waveguides 801 formed into a splitter section 813 (wherein the waveguides 801 are close enough to evanescently couple—shown in simplified form as a single waveguide in FIG. 8C) and a combiner section 815 (wherein the waveguides are close enough to evanescently couple) connected by two waveguides 801. In this embodiment the convolution modules 609 are formed within and over one of the connecting waveguides 801 between the splitter section 813 and the combiner section 815. In operation, the wavelength optical signals 606 is split in the splitter section 813, and one of the split signals is modulated by the convolution modules 609 before the modulated and unmodulated signals are combined in the combiner section 815.

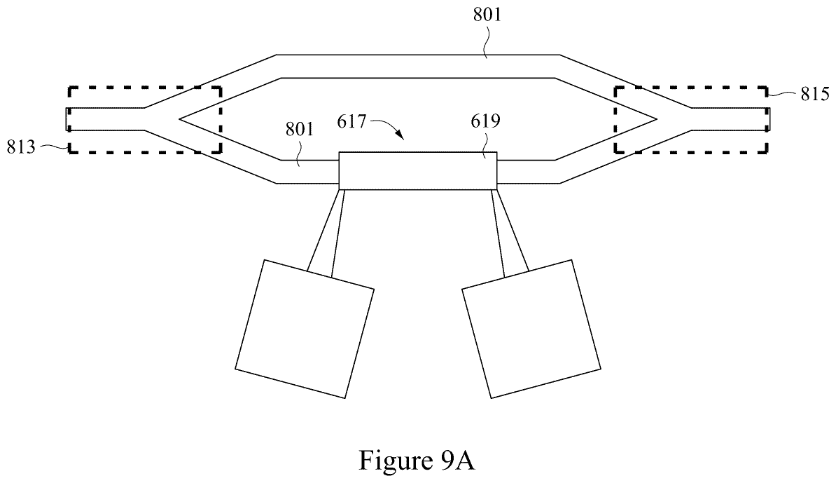

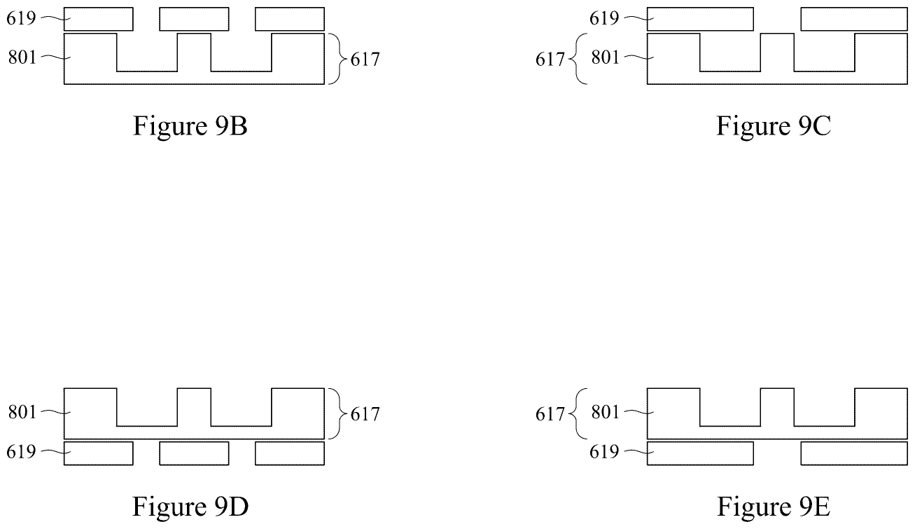

FIGS. 9A-9E illustrate yet another embodiment of the convolution modules 609 which may be used to modulate the wavelength optical signals 606. In this embodiment, however, instead of using a bias to modulate a PN junction, the convolution modules 609 utilize a heater in order to adjust the refraction index of the underlying material. In the particular embodiment illustrated in FIG. 9A the waveguides 801 are formed into the Mach-Zehnder modulator 811 (described above with respect to FIG. 8C) with the splitter section 813 and the combiner section 815 connected by two waveguides 801 in order to form the modulator unit 617.

In this embodiment, however, the weighting unit 619 is not simply connections that are used to apply a bias that will adjust the carrier concentrations, but are instead manufactured as heaters that physically heat one of the waveguides 801 within the modulator unit 617 in order to modulate the phase of the wavelength optical signals 606 as the wavelength optical signals 606 pass through the modulator unit 617.

For example, FIG. 9B illustrates a cross-sectional view of the waveguides 801 within the modulator unit 617 and the resistive heaters within the weighting unit 619. In an embodiment the heaters within the weighting unit 619 may be metal resistive heaters which comprise a metal material such as copper, aluminum, etc., which can be heated through, e.g., resistive heating as a current is run through the weighting unit 619. In an embodiment the heaters within the weighting unit 619 may be formed using similar processes and materials as the electrical components of the first metallization layer 501 (e.g., a damascene or dual damascene process). However, any suitable materials and any suitable processes may be utilized.

In the embodiment illustrated in FIG. 9B, there are multiple resistive heating elements within the weighting unit 619, wherein each heating element is directly heating a separate portion of the underlying waveguide 801. Each of the individual heating elements is located and formed over the waveguide 801, such as by being in an overlying layer of the first metallization layer 501. However, any suitable location may be utilized.

Looking next at FIG. 9C, there is illustrated another embodiment in which the multiple resistive heating elements are formed over the waveguides 801. In this embodiment there may be two heaters located over the waveguide 801, instead of the three heating elements illustrated in FIG. 9B. Any suitable number of resistive heating elements in any suitable configuration may be utilized.

FIGS. 9D and 9E illustrate cross-sectional views of the convolution modules 609 wherein the heating elements of the weighting unit 619 comprise three resistive heating elements (as illustrated in FIG. 9D) or two resistive heating elements (as illustrated in FIG. 9E). In these embodiments, however, instead of the heating elements being formed over the waveguides 801, the heating elements are formed below the waveguides 801. Any suitable configuration may be utilized.

In operation the convolution modules 609 achieve weighting through heating the waveguide 801. In particular, the refractive index of the waveguide 801 is changed by heating the waveguide 801 to shift the phase of the optical signals, thereby modulating the light intensity required for output, so that the output light energy changes relative to the weight value. As such, by modulating the output optical energy through heating the waveguide 801, the output optical energy varies with respect to the weight value thereby completing the weighting step.

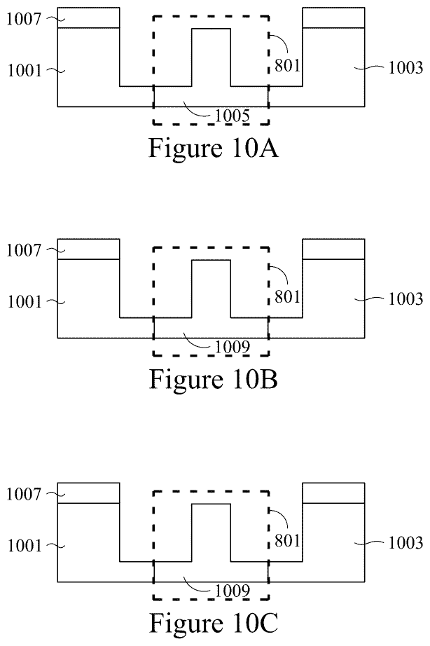

FIGS. 10A-10C illustrate cross-sectional views of embodiments in which the weighting unit 619 and the modulation units 617 are combined into using a material heater, such as a silicon heater. In the embodiment illustrated in FIG. 10A, the material 105 (see, e.g., FIG. 1) is illustrated as being patterned into a similar shape as the structure of FIG. 7B (e.g., a lateral PN junction (LPN) modulator without the implants). In this embodiment, however, the structure is implanted to form a first heating doped region 1001, a second heating doped region 1003, and a non-doped region 1005. In an embodiment the first heating doped region 1001 and the second heating doped region 1003 are similarly doped (e.g., either both N+ dopants or both P+ dopants) and may be formed using similar materials and processes as described above with respect to the second N-doped region 705 and the second P-doped region 709, described above with respect to FIG. 7B. However, any suitable materials and processes may be utilized.

The non-doped region 1005 is located between the first heating doped region 1001 and the second heating doped region 1003, and remains free of dopants or substantially free of dopants. For example, during an implantation process to form the first heating doped region 1001 and the second heating doped region 1003, the non-doped region 1005 is covered or otherwise protected. As such, while the dopants are implanted into the first heating doped region 1001 and the second heating doped region 1003, the non-doped region 1005 remains free of dopants.

Once the first heating doped region 1001, the second heating doped region 1003, and the non-doped region 1005 are formed, electrical connections 1007 are formed in physical and electrical connection with the first heating doped region 1001 and the second heating doped region 1003. In an embodiment the electrical connections 1007 are part of the first metallization layers 501 and are formed using, e.g., damascene or dual damascene processes with materials such as copper, tungsten, aluminum, combinations of these, or the like. However, any suitable methods and materials may be used.

During operation, a current is applied at one of the first heating doped region 1001 or the second heating doped region 1003 through the electrical connections 1007. At the non-doped region 1005 (or lightly doped region), it is harder for carriers to pass, which has an increased resistance to the current. The increased resistance causes the temperature of the non-doped region 1005 to increase, thereby increasing the refractive index of the non-doped region 1005 which also acts as the waveguide 801 through which the wavelength optical signals 606 pass.

FIG. 10B illustrates an embodiment in which the first heating doped region 1001 and the second heating doped region 1003 comprise N+-dopants. In this embodiment, however, instead of having the non-doped region 1005, a third heating doped region 1009 is formed within the waveguide between the first heating doped region 1001 and the second heating doped region 1003. In this embodiment, the third heating doped region 1009 comprises the same type of dopants as the first heating doped region 1001 and the second heating doped region 1003 (e.g., n-type dopants). However, the third heating doped region 1009 has a lower concentration of the dopants than either the first heating doped region 1001 and the second heating doped region 1003. As such, the resistance will increase within the third heating doped region 1009 when a current is passed through it, thereby raising the temperature and refractive index which modulates the wavelength optical signals 606.

FIG. 10C illustrates another embodiment that is similar to the embodiment illustrated in FIG. 10B. In this embodiment, instead of the first heating doped region 1001, the second heating doped region 1003, and the third heating doped region 1009 comprising N-type dopants, the first heating doped region 1001, the second heating doped region 1003, and the third heating doped region 1009 comprise P-type dopants. In particular, the first heating doped region 1001 and the second heating doped region 1003 may have a larger concentration of P-type dopants, while the third heating doped region 1009 has a lower concentration of P-type dopants.

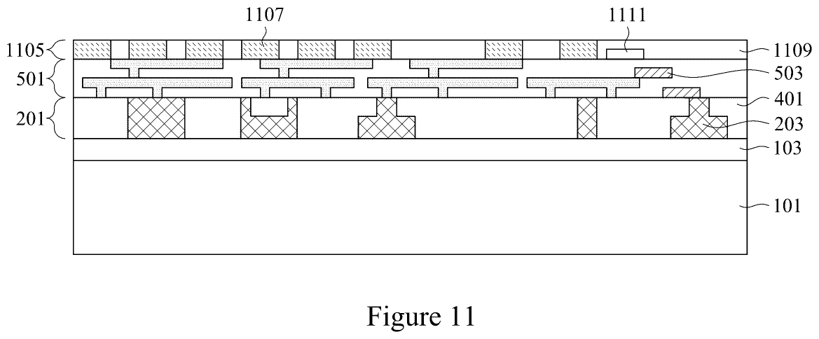

FIG. 11 illustrates that, once the first metallization layers 501 with the optical cores 601 have been manufactured, an optional first bonding layer 1105 is formed over the first metallization layers 501. In an embodiment, the first bonding layer 1105 may be used for a dielectric-to-dielectric and metal-to-metal bond. In accordance with some embodiments, the first bonding layer 1105 is formed of a first dielectric material 1109 such as silicon oxide, silicon nitride, or the like. The first dielectric material 1109 may be deposited using any suitable method, such as CVD, high-density plasma chemical vapor deposition (HDPCVD), PVD, atomic layer deposition (ALD), or the like. However, any suitable materials and deposition processes may be utilized.

Once the first dielectric material 1109 has been formed, first openings in the first dielectric material 1109 are formed to expose conductive portions of the underlying layers in preparation to form first bond pads 1107 within the first bonding layer 1105. Once the first openings have been formed within the first dielectric material 1109, the first openings may be filled with a seed layer and a plate metal to form the first bond pads 1107 within the first dielectric material 1109. The seed layer may be blanket deposited over top surfaces of the first dielectric material 1109 and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first dielectric material 1109 and sidewalls of the openings and the second openings before the seed layer. The barrier layer may comprise titanium, titanium nitride, tantalum, tantalum nitride, or the like.

Following the filling of the first openings, a planarization process, such as a CMP, is performed to remove excess portions of the seed layer and the plate metal, forming the first bond pads 1107 within the first bonding layer 1105. In some embodiments a bond pad via (not separately illustrated) may also be utilized to connect the first bond pads 1107 with underlying conductive portions and, through the underlying conductive portions, connect the first bond pads 1107 with the first metallization layers 501.

Additionally, the first bonding layer 1105 may also include one or more third optical components 1111 incorporated within the first bonding layer 1105. In such an embodiment, prior to the deposition of the first dielectric material 1109, the one or more third optical components 1111 may be manufactured using similar methods and similar materials as the one or more second optical components 503 (described above), such as by being waveguides and other structures formed at least in part through a deposition and patterning process. However, any suitable structures, materials and any suitable methods of manufacture may be utilized.

FIG. 12 illustrates a bonding of a first semiconductor device 1201 to the first bonding layer 1105. In some embodiments, the first semiconductor device 1201 is an electronic integrated circuit (EIC—e.g., a device without optical devices) and may have a semiconductor substrate 1203, a layer of active devices (not separately illustrated), an overlying interconnect structure (also not separately illustrated), a second bonding layer 1209, and associated third bond pads 1211. In an embodiment the semiconductor substrate 1203 may be similar to the first substrate 101 (e.g., a semiconductor material such as silicon or silicon germanium), the active devices may be transistors, capacitors, resistors, and the like formed over the semiconductor substrate 1203, the interconnect structure may be similar to the first metallization layers 501 (without optical components), the second bonding layer 1209 may be similar to the first bonding layer 1105, and the third bond pads 1211 may be similar to the first bond pads 1107. However, any suitable devices may be utilized.

Additionally, in some embodiments the second bonding layer 1209 is not formed adjacent to the interconnect structure, and the first semiconductor device 1201 may be formed with first through device vias 1213 (illustrated in FIG. 12 with dashed boxes) or through silicon vias in order to provide an electrical connection to a backside of the first semiconductor device 1201. In an embodiment the first through device vias 1213 may be formed by initially forming through device via openings into the semiconductor substrate 1203 prior to formation of the overlying interconnect structure and/or completion of the overlying interconnect structure. The through device via openings may be formed by applying and developing a suitable photoresist (not shown), and removing portions of the semiconductor substrate 1203 that are exposed.

Once the through device via openings have been formed, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may also be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used. If desired the second bonding layer 1209 may be formed in electric connection to the first through device vias 1213.

In an embodiment the first semiconductor device 1201 may be configured to work with the photonic integrated circuit 100 for a desired functionality. In some embodiments the first semiconductor device 1201 may be a high bandwidth memory (HBM) module in order to help form a Computation-in-Memory (CIM) architecture. However, in other embodiments the first semiconductor device 1201 may be an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

In an embodiment the first semiconductor device 1201 and the first bonding layer 1105 may be bonded using a dielectric-to-dielectric and metal-to-metal bonding process. In a particular embodiment which utilizes a dielectric-to-dielectric and metal-to-metal bonding process, the process may be initiated by activating the surfaces of the second bonding layer 1209 and the surfaces of the first bonding layer 1105. Activating the top surfaces of the first bonding layer 1105 and the second bonding layer 1209 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the first bonding layer 1105 and the second bonding layer 1209.

After the activation process the photonic integrated circuit 100 and the first semiconductor device 1201 may be cleaned using, e.g., a chemical rinse, and then the first semiconductor device 1201 is aligned and placed into physical contact with the photonic integrated circuit 100. The photonic integrated circuit 100 and the first semiconductor device 1201 are then subjected to thermal treatment and contact pressure to bond the photonic integrated circuit 100 and the laser die 600. For example, the photonic integrated circuit 100 and the first semiconductor device 1201 may be subjected to a pressure of about 200 kPa or less, and a temperature between about 25° C. and about 250° C. to fuse the photonic integrated circuit 100 and the first semiconductor device 1201. The photonic integrated circuit 100 and the first semiconductor device 1201 may then be subjected to a temperature at or above the eutectic point for material of the first bond pads 1107 and the third bond pads 1211, e.g., between about 150° C. and about 650° C., to fuse the metal. In this manner, the photonic integrated circuit 100 and the first semiconductor device 1201 forms a dielectric-to-dielectric and metal-to-metal bonded device. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

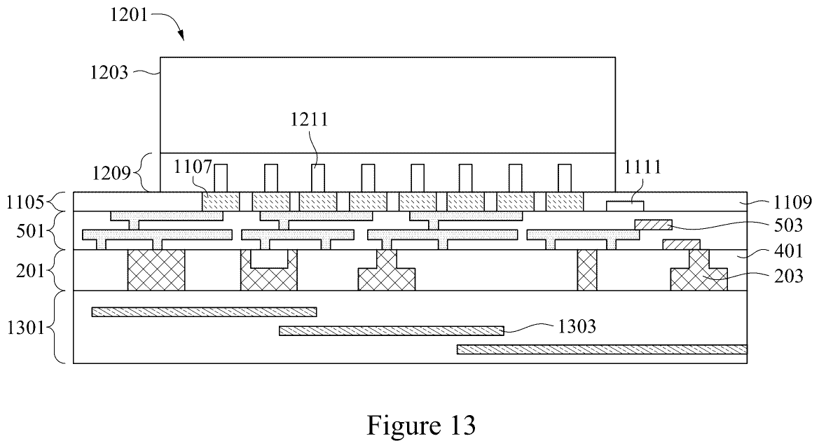

FIG. 13 illustrates a removal of the first substrate 101 and, optionally, the first insulator layer 103, thereby exposing the first active layer 201 of first optical components 203. In an embodiment the first substrate 101 and the first insulator layer 103 may be removed using a planarization process, such as a chemical mechanical polishing process, a grinding process, one or more etching processes, combinations of these, or the like. However, any suitable method may be used in order to remove the first substrate 101 and/or the first insulator layer 103.

Once the first substrate 101 and the first insulator layer 103 have been removed, a second active layer 1301 of fourth optical components 1303 may be formed on a back side of the first active layer 201. In an embodiment the second active layer 1301 of fourth optical components 1303 may be formed using similar materials and similar processes as the second optical components 503 of the first metallization layers 501 (described above with respect to FIG. 5). For example, the second active layer 1301 of fourth optical components 1303 may be formed of alternating layers of a cladding material such as silicon oxide and core material such as silicon nitride formed using deposition and patterning processes in order to form optical components such as waveguides and the like.

FIG. 14 illustrates formation of second through device vias (TDVs) 1401 and formation of a third bonding layer 1403 to complete the photonic integrated circuit 100 and form a first optical package 1400 (with both the photonic integrated circuit 100 and the first semiconductor device 1201). In an embodiment the second through device vias 1401 extend through the second active layer 1301 and the first active layer 201 so as to provide a quick passage of power, data, and ground through the photonic integrated circuit 100. In an embodiment the second through device vias 1401 may be formed by initially forming through device via openings into the photonic integrated circuit 100. The through device via openings may be formed by applying and developing a suitable photoresist (not shown), and removing portions of the second active layer 1301 and the photonic integrated circuit 100 that are exposed.

Once the through device via openings have been formed within the photonic integrated circuit 100, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may also be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Optionally, in some embodiments once the second through device vias 1401 have been formed, second metallization layers (not separately illustrated in FIG. 14) may be formed in electrical connection with the second through device vias 1401. In an embodiment the second metallization layers may be formed as described above with respect to the first metallization layers 501, such as being alternating layers of dielectric and conductive materials using damascene processes, dual damascene process, or the like. In other embodiments, the second metallization layers may be formed using a plating process to form and shape conductive material, and then cover the conductive material with a dielectric material. However, any suitable structures and methods of manufacture may be utilized.

The third bonding layer 1403 is formed in order to provide electrical connections between the photonic integrated circuit 100 and subsequently attached devices. In an embodiment the third bonding layer 1403 may be similar to the first bonding layer 1105, such as having third bond pads 1409 (similar to the first bond pads 1107) and even fifth optical components 1411 (similar to the third optical components 1111). However, any suitable devices may be utilized.

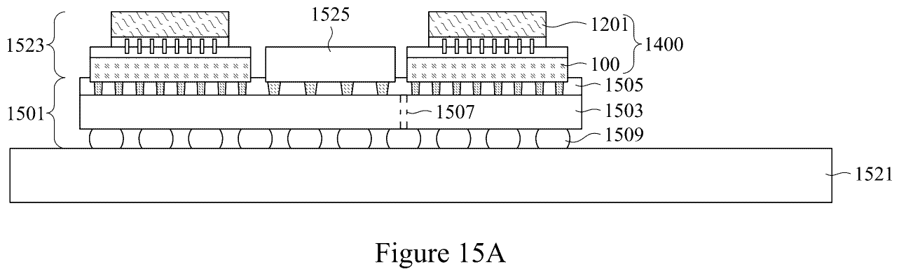

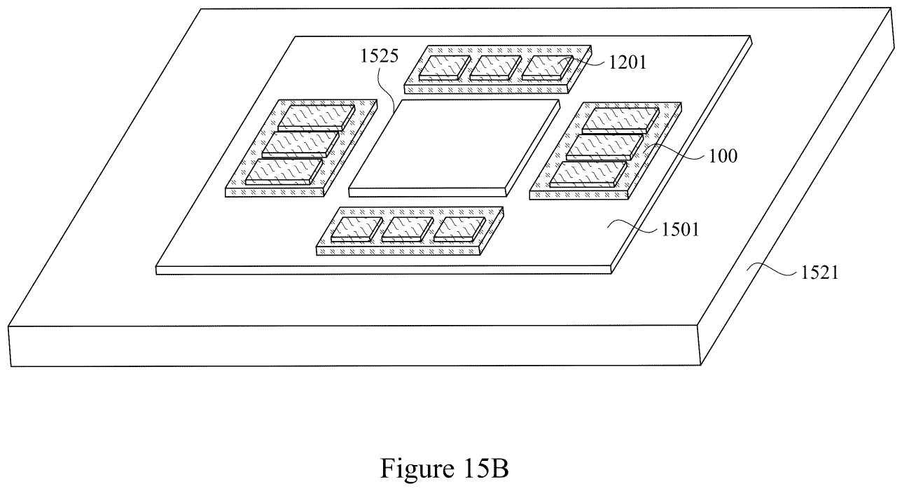

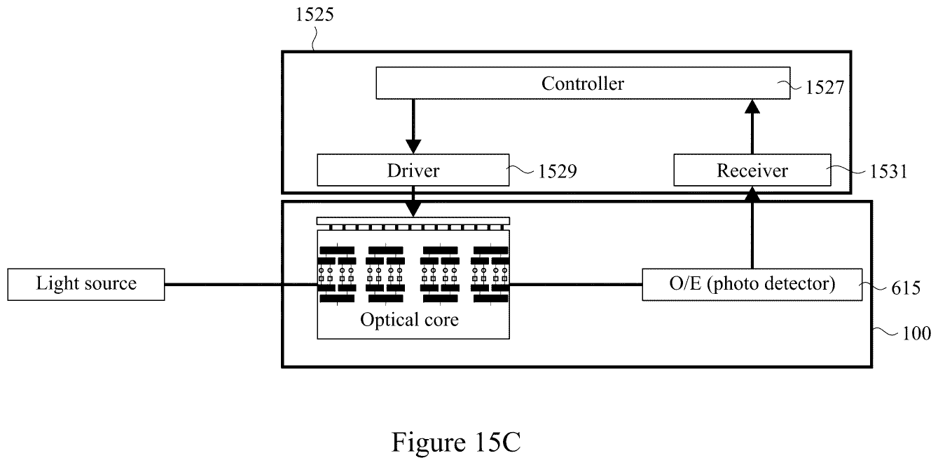

FIG. 15A illustrates that once the first optical package 1400 has been formed (with FIG. 15A illustrating a simplified form of the various structures), the first optical package 1400 may be attached to an interposer substrate 1501 that is used to couple the first optical package 1400 with other devices to form, for example, a chip-on-wafer-on-substrate (CoWoS®) device. In an embodiment the interposer substrate 1501 comprises a semiconductor substrate 1503, third metallization layers 1505, third through device vias (TDVs) 1507 (only one of which is illustrated in FIG. 15A), and first external connectors 1509. The semiconductor substrate 1503 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

Optionally, first active devices (not separately illustrated) may be added to the semiconductor substrate 1503. The first active devices comprise a wide variety of active devices and passive devices such as capacitors, resistors, inductors and the like that may be used to generate the desired structural and functional requirements of the design for the semiconductor substrate 1503. The first active devices may be formed using any suitable methods either within or else on the semiconductor substrate 1503.

The third metallization layers 1505 are formed over the semiconductor substrate 1503 and the first active devices and are designed to connect the various devices to form functional circuitry. In an embodiment the third metallization layers 1505 are formed of alternating layers of dielectric (e.g., low-k dielectric materials, extremely low-k dielectric material, ultra low-k dielectric materials, combinations of these, or the like) and conductive material and may be formed through any suitable process (such as deposition, damascene, dual damascene, etc.). However, any suitable materials and processes may be utilized.

Additionally, at any desired point in the manufacturing process, the third TDVs 1507 may be formed within the semiconductor substrate 1503 and, if desired, one or more layers of the third metallization layers 1505, in order to provide electrical connectivity from a front side of the semiconductor substrate 1503 to a back side of the semiconductor substrate 1503. In an embodiment the third TDVs 1507 may be formed by initially forming through device via (TDV) openings into the semiconductor substrate 1503 and, if desired, any of the overlying third metallization layers 1505 (e.g., after the desired third metallization layer has been formed but prior to formation of the next overlying third metallization layer). The TDV openings may be formed by applying and developing a suitable photoresist, and removing portions of the underlying materials that are exposed to a desired depth. The TDV openings may be formed so as to extend into the semiconductor substrate 1503 to a depth greater than the eventual desired height of the semiconductor substrate 1503.

Once the TDV openings have been formed within the semiconductor substrate 1503 and/or any third metallization layers 1505, the TDV openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used.

Once the liner has been formed along the sidewalls and bottom of the TDV openings, a barrier layer may be formed and the remainder of the TDV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TDV openings. Once the TDV openings have been filled, excess liner, barrier layer, seed layer, and first conductive material outside of the TDV openings may be removed through a planarization process such as chemical mechanical polishing (CMP), although any suitable removal process may be used.

Once the TDV openings have been filled, the semiconductor substrate 1503 may be thinned until the third TDVs 1507 have been exposed. In an embodiment the semiconductor substrate 1503 may be thinned using, e.g., a chemical mechanical polishing process, a grinding process, or the like. Further, once exposed, the third TDVs 1507 may be recessed using, e.g., one or more etching processes, such as a wet etch process in order to recess the semiconductor substrate 1503 so that the third TDVs 1507 extend out of the semiconductor substrate 1503.

In an embodiment the first external connectors 1509 may be placed in electrical connection with the third TDVs 1507 and may be, e.g., a ball grid array (BGA) which comprises a eutectic material such as solder, although any suitable materials may be used. Optionally, an underbump metallization or additional metallization layers (not separately illustrated in FIG. 15A) may be utilized between the third TDVs 1507 and the first external connectors 1509. In an embodiment in which the first external connectors 1509 are solder bumps, the first external connectors 1509 may be formed using a ball drop method, such as a direct ball drop process. In another embodiment, the solder bumps may be formed by initially forming a layer of tin through any suitable method such as evaporation, electroplating, printing, solder transfer, and then performing a reflow in order to shape the material into the desired bump shape. Once the first external connectors 1509 have been formed, a test may be performed to ensure that the structure is suitable for further processing.

Once the interposer substrate 1501 has been formed, the first optical package 1400 may be attached to the interposer substrate 1501. In an embodiment the first optical package 1400 may be attached to the interposer substrate 1501 by using a dielectric-to-dielectric and metal-to-metal bonding process as described above with respect to FIG. 12, thereby bonding the third bonding layer 1403 to conductive portions of the interposer substrate 1501, such as the third metallization layers 1505 (in the embodiment illustrated), the third TDVs 1507, or a separate bonding layer (not illustrated).

Additionally, in other embodiments the third bonding layer 1403 on the photonic integrated circuit 100 may be omitted. In such an embodiment the bonding process may directly bond the second through device vias 1401 of the photonic integrated circuit 100 to the conductive elements of the interposer substrate 1501, such as the third TDVs 1507, the third metallization layers 1505, or a separate bonding layer. Any suitable combination of bonding elements may be used, and all such combinations are fully intended to be included within the scope of the embodiments.

FIG. 15A additionally illustrates a bonding of a second optical package 1523 to the interposer substrate 1501. In an embodiment the second optical package 1523 may be formed using similar devices, processes, and materials as the first optical package 1400, and may be bonded using a similar bonding process. However, any suitable devices, with any suitable functionalities, may be utilized.

FIG. 15A also illustrates a bonding of a second semiconductor device 1525 to the interposer substrate 1501. In an embodiment the second semiconductor device 1525 may be a system on chip device, such as a logic device, which is intended to work in conjunction with the first optical package 1400 and the second optical package 1523. However, any suitable functionality, such as logic dies, central processing unit (CPU) dies, input/output dies, combinations of these, or the like, may be utilized.

Once the first optical package 1400, the second optical package 1523, and the second semiconductor device 1525 have been bonded to the interposer substrate 1501, the interposer substrate 1501 may be bonded to a second substrate 1521 with, e.g., the first external connectors 1509. In an embodiment the second substrate 1521 may be a package substrate, which may be a system board such as a printed circuit board (PCB) or the like. The second substrate 1521 may include one or more dielectric layers and electrically conductive features, such as conductive lines and vias. In some embodiments, the second substrate 1521 may include through-vias, active devices, passive devices, and the like. The second substrate 1521 may further include conductive pads formed at the upper and lower surfaces of the second substrate 1521.

The first external connectors 1509 may be aligned with corresponding conductive connections on the second substrate 1521. Once aligned the first external connectors 1509 may then be reflowed in order to bond the second substrate 1521 to the interposer substrate 1501. However, any suitable bonding process may be used to connect the interposer substrate 1501 to the second substrate 1521.

FIG. 15B illustrates a perspective view of the structure of FIG. 15A. As can be seen, multiple ones of the first semiconductor devices 1201 (e.g., memory dies) are attached to the photonic integrated circuit 100 in order to form the first optical packages 1400. Additionally, multiple optical packages (e.g., the first optical package 1400, the second optical package 1523, and other optical packages) are attached to the interposer substrate 1501. The second semiconductor device 1525 is also bonded to the interposer substrate 1501, and the interposer substrate 1501 is bonded to the second substrate 1521.

By integrating the first semiconductor device 1201 onto the photonic integrated circuit 100 and integrating the first optical package 1400 and the second semiconductor device 1525 onto the interposer substrate 1501, advantages can be achieved. For example, a high density, high speed, and low power consumption device can be achieved. Such a high density, high speed, and low power consumption device can be applied to high-performance computing and artificial intelligence.

FIG. 15C illustrates a conceptual diagram of the operation of the photonic integrated circuit 100 with the second semiconductor device 1525. As illustrated the photonic integrated circuit 100 comprises the optical core 601 while the second semiconductor device 1525 comprises a controller 1527, a driver 1529, and a receiver 1531. In operation, the photonic integrated circuit 100 receives the optical signals 602 (e.g., lasers) along with an electrical driver signal from the driver 1529 of the second semiconductor device 1525. The optical signals created by the optical core 601 are sent to the photodiode/transimpedance amplifier 615 (e.g., a photodetector) located either within the photonic integrated circuit 100 (as illustrated in FIG. 15C) or else on another device, which then sends the electrical signal to the receiver 1531 within the second semiconductor device 1525 and eventually to the controller 1527.

By using the optoelectronic hybrid architecture proposed herein, a Memory in Computation (MIC) technology which combines computation and storage can be used that reduces data transfer and latency and improves computation efficiency. In particular, optical components and photonic integrated circuits are used to perform high-speed and high-bandwidth computations such as matrix operations. For example, the photonic integrated circuit 100 along with the first semiconductor device 1201 integrated together perform matrix computations, wherein data is read directly from the storage unit (e.g., the first semiconductor device 1201), computation are performed with the read data (on the photonic integrated circuit 100, and the result sent back to the storage unit (e.g., the first semiconductor device 1201), thereby reducing data transfer and latency and improving computation efficiency. Additionally, if desired, after computations are completed, the optical signal is converted back to an electrical signal for result classification and processing using electrical circuits, helping to ensure the accuracy and reliability of the computation results.

By integrating MIC technology and optical components, the optoelectronic hybrid architecture can achieve faster and more accurate AI computations while reducing signal latency during computation. Moreover, the use of MIC technology allows for the direct use of storage units during computation, reducing data transfer and latency and improving computation efficiency.

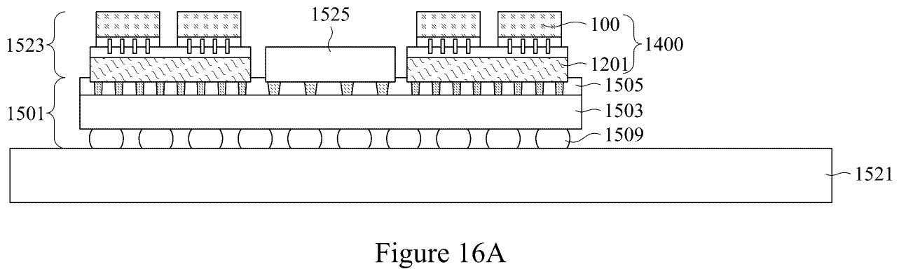

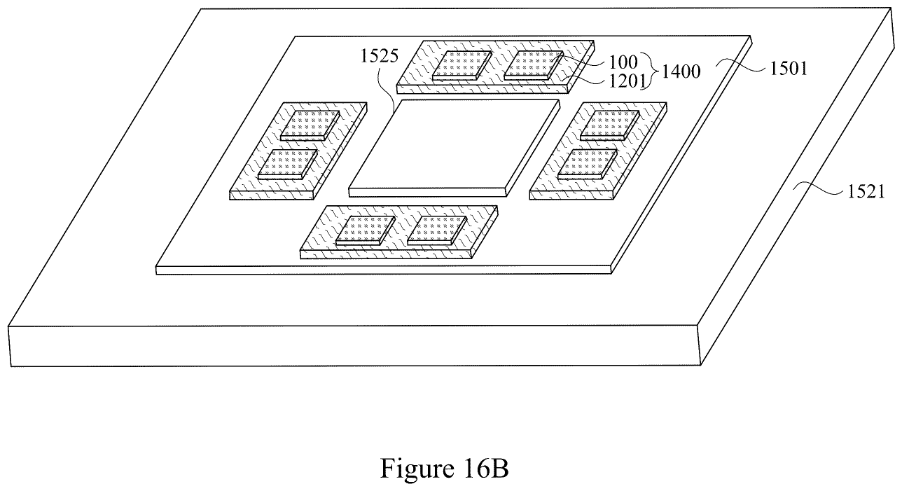

FIGS. 16A-16B illustrate another embodiment that is similar to the embodiment illustrated in FIGS. 15A-15B in which the first optical package 1400 is bonded to the interposer substrate 1501. In this embodiment, however, instead of the photonic integrated circuit 100 being bonded to the interposer substrate 1501, the first semiconductor device 1201 (e.g., a memory device) is bonded to the interposer substrate 1501 (using, e.g., the first through device vias 1213 discussed in FIG. 12 and, optionally, an bonding layer over the first through device vias 1213). In this embodiment the photonic integrated circuit 100 may be bonded to the first semiconductor device 1201 using either the first bonding layer 1105 (wherein the second through device vias 1401 and the third bonding layer 1403 are not necessarily formed) or using the third bonding layer 1403 (wherein the first bonding layer 1105 is not necessarily formed).

Additionally, in this embodiment multiple ones of the photonic integrated circuits 100 may be bonded to the first semiconductor device 1201 in order to form the first optical package 1400. Further, multiple ones of the first optical package 1400 may be bonded to the interposer substrate 1501, such as the second optical package 1523, and the second semiconductor device 1525 are also bonded to the interposer substrate 1501. Finally, the interposer substrate 1501 is bonded to the second substrate 1521.

FIG. 16B illustrates a perspective view of an embodiment utilizing a similar structure as illustrated in FIG. 16A. As can be seen, multiple ones of the photonic integrated circuit 100 are attached to the first semiconductor device 1201 in order to form the first optical packages 1400. Additionally, multiple optical packages (e.g., the first optical package 1400, the second optical package 1523, etc.) are attached to the interposer substrate 1501. The second semiconductor device 1525 is also bonded to the interposer substrate 1501, and the interposer substrate 1501 is bonded to the second substrate 1521.

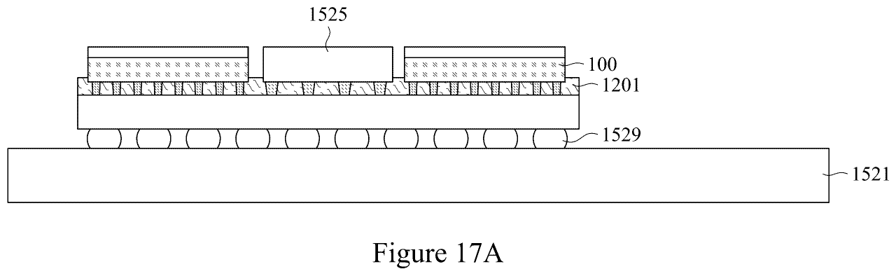

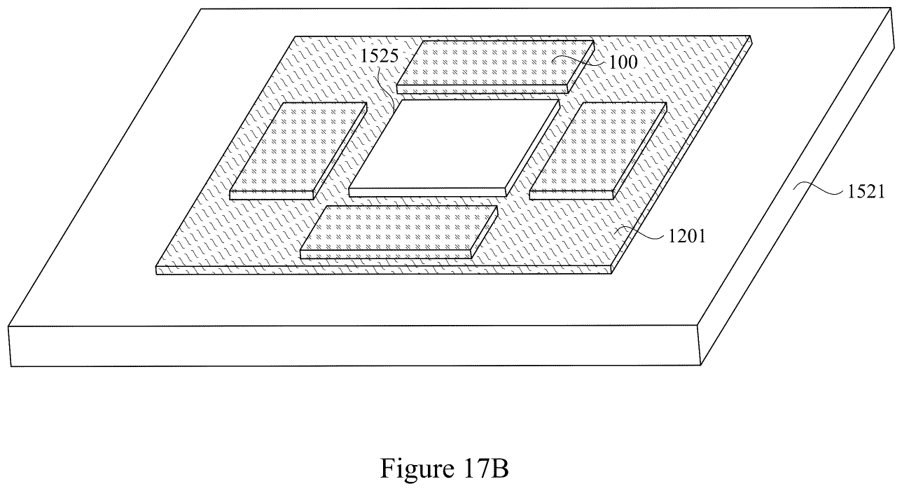

FIGS. 17A-17B illustrate yet another embodiment in which the photonic integrated circuit 100 is bonded to the first semiconductor device 1201. In this embodiment, however, each of the photonic integrated circuits 100 is bonded to the first semiconductor device 1201 and the second semiconductor device 1525 is also bonded to the first semiconductor device 1201. Additionally in this embodiment, the interposer substrate 1501 (see, e.g., FIG. 16A) is not utilized, and the first external connectors 1509 are formed on the first semiconductor device 1201 (e.g., in electrical connection with the first through device vias 1213 or the second bonding layer 1209). Once the first external connectors 1509 are formed, the first semiconductor device 1201 may be bonded directly to the second substrate 1521. However, any suitable structures may be utilized.

FIG. 17B illustrates a perspective view of an embodiment utilizing a similar structure as illustrated in FIG. 17A. As can be seen, multiple ones of the photonic integrated circuit 100 are attached to the first semiconductor device 1201 along with the second semiconductor device 1525. The first semiconductor device 1201 is also bonded directly to the second substrate 1521 without the use of the interposer substrate 1501.

By using the first semiconductor device 1201 as an integrated platform, the photonic integrated circuit 100 and the second semiconductor device 1525 can be integrated into a single package. As such, the overall device can effectively reduce temperature and prevent noise or other loses during high-speed and high-performance calculations. As such, a more efficient overall device can be achieved.

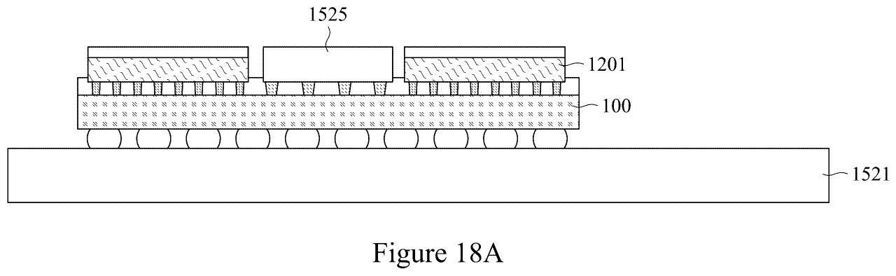

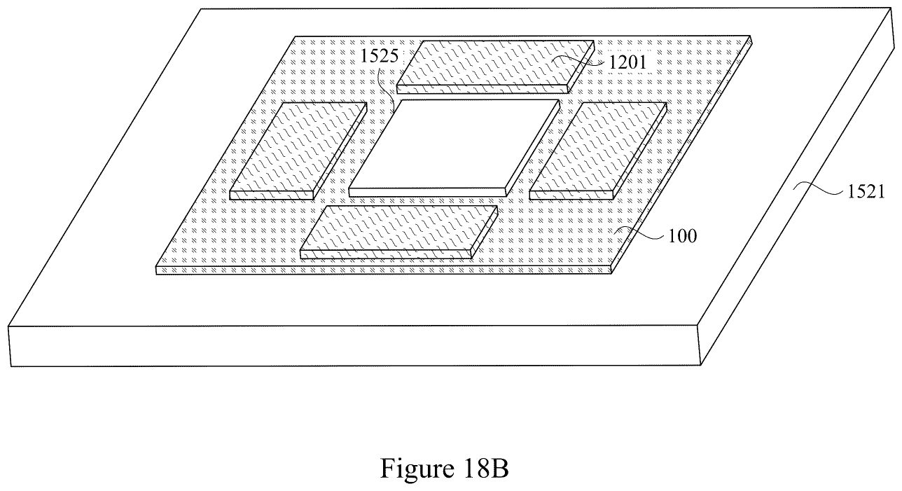

FIGS. 18A-18B illustrate yet another embodiment in which the interposer substrate 1501 is not utilized. In this embodiment, instead of multiple photonic integrated circuits 100 being bonded to a single first semiconductor device 1201, multiple ones of the first semiconductor devices 1201 are bonded to a single one of the photonic integrated circuits 100. Additionally in this embodiment, the interposer substrate 1501 (see, e.g., FIG. 16A) is not utilized, and the first external connectors 1509 are formed on the photonic integrated circuit 100 (e.g., in electrical connection with the third bonding layer 1403 or the first bonding layer 1105). Additionally, the second semiconductor device 1525 is bonded to the photonic integrated circuit 100, and the photonic integrated circuit 100 is directly bonded to the second substrate 1521 without the use of the interposer substrate 1501.

FIG. 18B illustrates a perspective view of an embodiment utilizing a similar structure as illustrated in FIG. 18A. As can be seen, multiple ones of the first semiconductor devices 1201 are attached to a single one of the photonic integrated circuit 100 along with the second semiconductor device 1525. The photonic integrated circuit 100 is also bonded directly to the second substrate 1521.

By using the photonic integrated circuit 100 as an integrated platform, the first semiconductor device 1201 and the second semiconductor device 1525 can be integrated into a single package. As such, the overall device can effectively reduce temperature and prevent noise or other loses during high-speed and high-performance calculations. As such, a more efficient overall device can be achieved.

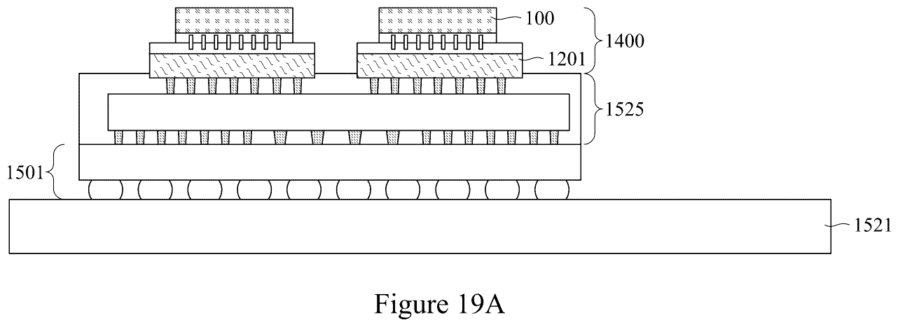

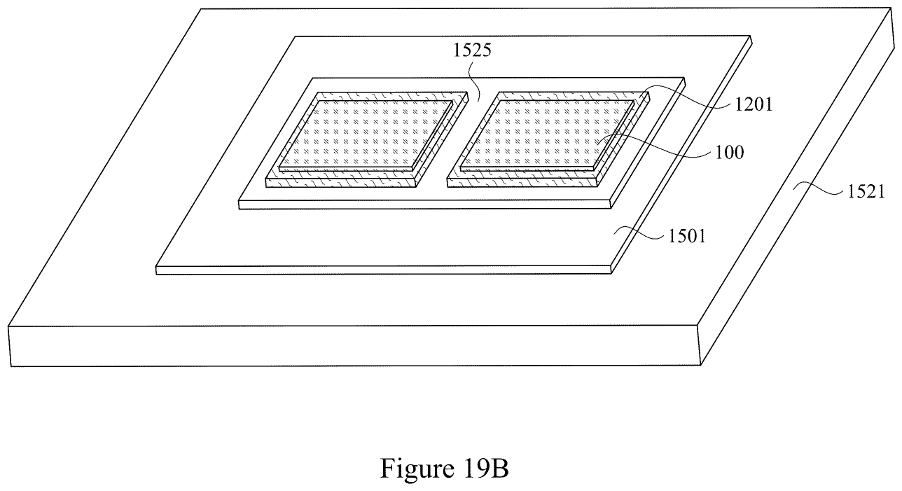

FIGS. 19A-19B illustrate yet another embodiment that includes the interposer substrate 1501. In this embodiment, multiple ones of the first optical package 1400 (which includes the photonic integrated circuit 100 and the first semiconductor device 1201) are bonded to the second semiconductor device 1525 (which is illustrated in this figure as having the metallization layers to connect to external devices). Additionally, the second semiconductor device 1525 is bonded directly to the interposer substrate 1501, and the interposer substrate 1501 is bonded to the second substrate 1521.

FIG. 19B illustrates a perspective view of an embodiment utilizing a similar structure as illustrated in FIG. 19A. As can be seen, multiple ones of the first semiconductor devices 1201 (each with an attached photonic integrated circuit 100) are attached to a single one of the second semiconductor device 1525. The second semiconductor device 1525 is also bonded directly to the interposer substrate 1501, and the interposer substrate 1501 is directly bonded to the second substrate 1521.

By using the second semiconductor device 1525 as a substrate, the first semiconductor device 1201 and the photonic integrated circuit 100 can be integrated into a single package. As such, multiple independent and high-density, high-speed, and low-power advantages can be achieved, while achieving higher packaging density and better heat dissipation. Such an integration can also reduce electromagnetic interference between chips.

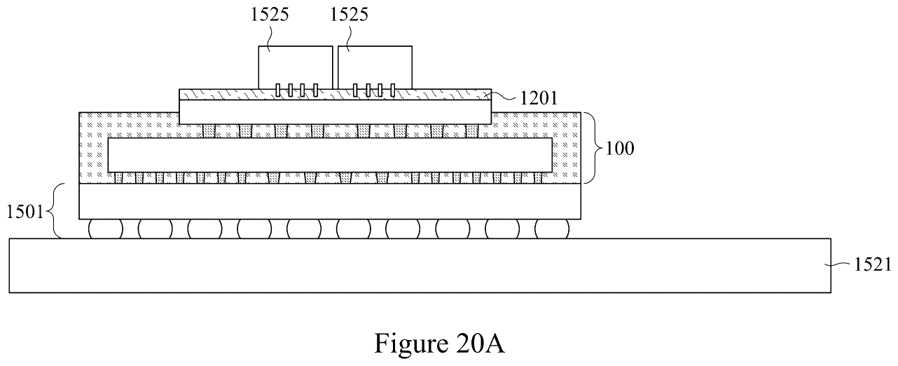

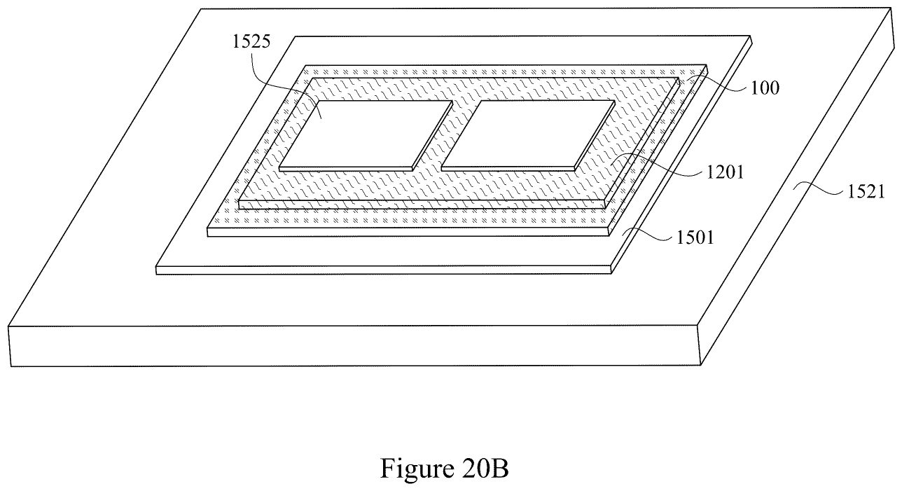

FIGS. 20A-20B illustrate yet another embodiment that includes the interposer substrate 1501. In this embodiment, multiple ones of the second semiconductor device 1525 are bonded to the first semiconductor device 1201. Additionally, the first semiconductor device 1201 is bonded directly to the photonic integrated circuit 100 (illustrated in this figure in a simplified form), the photonic integrated circuit 100 is directly bonded to the interposer substrate 1501, and the interposer substrate 1501 is bonded to the second substrate 1521.

FIG. 20B illustrates a perspective view of an embodiment utilizing a similar structure as illustrated in FIG. 20A. As can be seen, multiple ones of the second semiconductor devices 1525 are attached to a single one of the first semiconductor device 1201. The first semiconductor device 1201 is bonded directly to the photonic integrated circuit 100, the photonic integrated circuit 100 is directly bonded to the interposer substrate 1501, and the interposer substrate 1501 is bonded to the second substrate 1521.

By using the photonic integrated circuit 100 as a substrate, the first semiconductor device 1201 and the second semiconductor device 1525 can be integrated into a single package. Such an integration produces multiple sets of independent and high-density, high-speed, and low-power advantages while achieving higher packaging density and better heat dissipation. Furthermore, this integration can reduce electromagnetic interference between chips. Further, the second semiconductor devices 1525 can operate through a large amount of memory (e.g., within the first semiconductor device 1201) and also efficiently perform high-speed operations through the photonic integrated circuit 100. The independent second semiconductor devices 1525 also reduces the thermal interaction effect, and the large area of the photonic integrated circuit 100 provides cooling advantages without generating additional heat.

By utilizing the proposed structures and methods as detailed herein, a hybrid optical-electrical AI architecture can solve latency problems by using optical integrated circuits to replace transitional electronic computing cores. The electrical circuit for classifying computation results is retained, with electrical signals transmitted to the optical computer core and computer optical signals being converted back to electrical signals for feedback. The optical components high bandwidth characteristics increase the overall amount of synchronized computations.

In particular, the proposed structures and methods assist to accelerate computing speed (e.g., using silicon photonics technology for signal transmission can provide higher bandwidth, thereby accelerating computing speed), reduce system power consumption (e.g., silicon photonics technology consumes less energy during computation, thereby reducing system power consumption), solve latency problems (e.g., by using optical integrated circuits to replace traditional electronic computing cores, signal delay problems are solved and further improving computing efficiency), improve computing efficiency (e.g., using silicon photonics technology for signal transmission can provide higher bandwidth, thereby accelerating computing speed, while also reducing system power consumption, further improving computing efficiency), and increase synchronous computing amount (e.g., high bandwidth characteristics of optical components can also increase synchronous computing amount, thereby improving computing speed and efficiency). Additionally, the ideas presented herein can be applied in a wide application, such as high-speed data transmission, high-performance computing, optoelectronic transistor chips, and other fields, with wide application prospects, especially in computer integrated manufacturing.

In an embodiment, a method of manufacturing an optical device includes: forming a first photonic integrated circuit, the photonic integrated circuit comprising a photonic neural network; bonding a first semiconductor device to the first photonic integrated circuit; and electrically connecting a second semiconductor device to the first photonic integrated circuit. In an embodiment the photonic integrated circuit comprises a convolution module. In an embodiment the convolution module comprises a phase modulator based on a PN junction. In an embodiment the PN junction is a lateral PN junction. In an embodiment the convolution module is part of a ring modulator. In an embodiment the convolution module is part of a Mach-Zehnder modulator. In an embodiment the convolution module comprises a heating element.

In another embodiment, a method of manufacturing an optical device includes: forming a modulation unit and a weighting unit as part of a photonic integrated circuit; connecting a memory device to the photonic integrated circuit to form a first photonic package; bonding the first photonic package to an interposer substrate; and bonding a system-on-chip device to the interposer substrate. In an embodiment the bonding the first photonic package bonds the photonic integrated circuit to the interposer substrate. In an embodiment the bonding the first photonic package bonds the memory device to the interposer substrate. In an embodiment the system-on-chip device comprises a controller for the weighting unit. In an embodiment the forming the modulation unit and the weighting unit forms a metal heating element over a waveguide. In an embodiment the forming the modulation unit and the weighting unit forms a metal heating element beneath a waveguide. In an embodiment the forming the weighting unit forms a silicon heater.

In yet another embodiment an optical device includes: a photonic integrated circuit, the photonic integrated circuit comprising a photonic neural network; a memory device bonded to the photonic integrated circuit; and a system-on-chip device in electrical connection with the photonic integrated circuit. In an embodiment the photonic integrated circuit and the system-on-chip device are bonded to an interposer substrate. In an embodiment the memory device and the system-on-chip device are bonded to an interposer substrate. In an embodiment the system-on-chip device is bonded to the memory device. In an embodiment the system-on-chip device is bonded to the photonic integrated circuit. In an embodiment the memory device is bonded to the system-on-chip device, and further comprising a second memory device bonded to the system-on-chip device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an optical device, the method comprising:
forming a first photonic integrated circuit, the photonic integrated circuit comprising a photonic neural network;
bonding a first semiconductor device to the first photonic integrated circuit; and
electrically connecting a second semiconductor device to the first photonic integrated circuit.

2. The method of claim 1, wherein the photonic integrated circuit comprises a convolution module.

3. The method of claim 2, wherein the convolution module comprises a phase modulator based on a PN junction.

4. The method of claim 3, wherein the PN junction is a lateral PN junction.

5. The method of claim 3, wherein the convolution module is part of a ring modulator.

6. The method of claim 3, wherein the convolution module is part of a Mach-Zehnder modulator.

7. The method of claim 2, wherein the convolution module comprises a heating element.

8. A method of manufacturing an optical device, the method comprising:
forming a modulation unit and a weighting unit as part of a photonic integrated circuit;
connecting a memory device to the photonic integrated circuit to form a first photonic package;
bonding the first photonic package to an interposer substrate; and
bonding a system-on-chip device to the interposer substrate.

9. The method of claim 8, wherein the bonding the first photonic package bonds the photonic integrated circuit to the interposer substrate.

10. The method of claim 8, wherein the bonding the first photonic package bonds the memory device to the interposer substrate.

11. The method of claim 8, wherein the system-on-chip device comprises a controller for the weighting unit.

12. The method of claim 8, wherein the forming the modulation unit and the weighting unit forms a metal heating element over a waveguide.

13. The method of claim 8, wherein the forming the modulation unit and the weighting unit forms a metal heating element beneath a waveguide.

14. The method of claim 8, wherein the forming the weighting unit forms a silicon heater.

15. An optical device comprising:
a photonic integrated circuit, the photonic integrated circuit comprising a photonic neural network;
a memory device bonded to the photonic integrated circuit; and
a system-on-chip device in electrical connection with the photonic integrated circuit.

16. The optical device of claim 15, wherein the photonic integrated circuit and the system-on-chip device are bonded to an interposer substrate.

17. The optical device of claim 15, wherein the memory device and the system-on-chip device are bonded to an interposer substrate.

18. The optical device of claim 15, wherein the system-on-chip device is bonded to the memory device.

19. The optical device of claim 15, wherein the system-on-chip device is bonded to the photonic integrated circuit.

20. The optical device of claim 15, wherein the memory device is bonded to the system-on-chip device, and further comprising a second memory device bonded to the system-on-chip device.
